(19) United States
(12) Patent Application Publication
(10) Pub. No.: US 2025/0179639 A1
(43) Pub. Date: Jun. 5, 2025

(54) HARDWARE DESIGN WITH INDEPENDENT CONTROL TO IMPROVE WIW UNIFORMITY

(71) Applicant: Applied Materials, Inc., Santa Clara, CA (US)

(72) Inventors: Rupankar CHOUDHURY, BANGALORE (IN); Chidambara A. RAMALINGAM, Fremont, CA (US); Mukesh Singh DHAMI, Bangalore (IN); Udit Suryakant KOTAGI, Singapore (SG)

(21) Appl. No.: 18/526,788

(22) Filed: Dec. 1, 2023

(51) Int. Cl. C23C 16/455; C23C 16/50; H01J 37/32; H01L 21/02

(52) U.S. Cl. CPC C23C 16/45591; C23C 16/45561; C23C 16/50; H01J 37/3244; H01L 21/02274; H01J 2237/3321

(57) ABSTRACT

A baffle for providing process gas into a processing volume of a vacuum process chamber including body having a first end connectable to a gas source and a second end distal to the first end, the second end including at least a first frustoconical surface and a second frustoconical surface extending around the first frustoconical surface, and, an outer surface extending from the proximal end to the distal end, a first gas feed passage extending inwardly of the body from the proximal end, the first gas feed passage disposed inwardly of the body, at least one first discharge passage extending from the distal end of the first gas feed passage and opening through the first frustoconical surface, at least one second gas feed passage extending inwardly of the body from the proximal end thereof, the second gas passage disposed inwardly of the body and fluidly isolated from the first gas feed passage.

### BACKGROUND

### Field

Embodiments of the present disclosure generally relate to the field of semiconductor processing equipment. More particularly, the present invention relates to methods and apparatus for depositing thin films, for example with gas distributors, used in the formation of integrated circuits.

### Description of the Related Art

One of the primary steps in the fabrication of modem semiconductor devices is the formation of a this film layer, such as a silicon oxide or silicon nitride film layer, on a semiconductor substrate or on previously formed layers on the substrate. Silicon oxide is widely used as dielectric layer in the manufacture of semiconductor devices. As is well known, a silicon oxide film layer, a silicon nitride film layer, or other layers can be deposited by a thermal chemical-vapor deposition (“CVD”) process or by a plasma-enhanced chemical-vapor deposition (“PECVD”) process. In a conventional thermal CVD process, reactive gases are supplied to a surface of the substrate, such as the substrate itself or on a layer previously formed or processed thereon, where heat-induced chemical reactions take place to produce a desired film. In a conventional plasma-deposition process, a controlled plasma is formed to decompose and/or energize reactive species to produce the desired film.

Semiconductor device geometries have decreased significantly in size since such devices were first introduced several decades ago, and continue to be reduced in size. This continuing reduction in the scale of device geometry has resulted in a dramatic increase in the density of circuit elements and interconnections formed in integrated circuits fabricated on a semiconductor substrate. One persistent challenge faced by semiconductor manufacturers in the design and fabrication of such densely packed integrated circuits is the desire to prevent spurious interactions between circuit elements of one or more devices being formed on the substrate, a goal that has required ongoing innovation as the geometry scale of the devices and the material layers therein continue to decrease.

Unwanted interactions between the elements of a device on a substrate are typically prevented by providing spaces between adjacent elements that are then filled with a dielectric material to isolate the elements both physically and electrically. For example, a metal or semiconductor film layer can be etched to provide isolated regions thereof with spaces therebetween. Such spaces are sometimes referred to herein as “gaps” or “trenches,” and the processes for filling such spaces are commonly referred to in the art as “gapfill” processes. The ability of a given process to produce a film that completely fills such gaps is thus often referred to as the “gapfill ability” of the process, with the film described as a “gapfill layer” or “gapfill film.” As circuit densities increase with smaller feature sizes, the widths of these gaps has decreased, resulting in an increase in their aspect ratio, which is defined by the ratio of the gap's height to its depth. High-aspect-ratio gaps are difficult to fill completely using conventional CVD techniques, which tend to have relatively poor gapfill abilities. One family of dielectric films that is commonly used to fill gaps in intermetal dielectric (“IMD”) applications, premetal dielectric (“PMD”) applications, and shallow-trench-isolation (“STI”) applications, among others, is silicon oxide (sometimes also referred to as “silica glass” or “silicate glass”).

Some integrated circuit manufacturers have turned to the use of high-density plasma CVD (“HDP-CVD”) systems in depositing silicon oxide gapfill layers. Such systems form a plasma that has a density greater than about 10¹¹ ions/cm³, which is about two orders of magnitude greater than the plasma density provided by a standard capacitively coupled plasma CVD system. Inductively coupled plasma (“ICP”) systems are examples of HDP-CVD systems. One factor that allows films deposited by such HDP-CVD techniques to have improved gapfill characteristics is the biasing of the substrate to attract ions from the plasma to simultaneously sputter and deposit the material being deposited. Sputtering is a mechanical process by which a portion of the deposited material is ejected by impact of plasma ions thereagainst, and is promoted by the high ionic density of the plasma in HDP-CVD processes. The sputtering component of HDP deposition thus slows deposition on certain features, such as the corners of raised surfaces, thereby contributing to the increased gapfill ability.

Even with the use of HDP and ICP processes, there remain a number of persistent challenges in achieving desired deposition properties. These include the need to provide deposition processes that are uniform across a wafer to result in a uniform thickness deposited layer across the surface of the substrate on which the deposition occurs. Non-uniformity of deposited material layer thickness across the surface of the substrate may lead to inconsistencies in device performance. The deposition characteristics at different points over a wafer result from a complex interplay of a number of different effects. For example, the way in which gas is introduced into the chamber, the level of power used to ionize precursor species, the use of electrical fields to direct ions, and the like, may ultimately affect the uniformity of deposition characteristics across a wafer. In addition, the way in which these effects are manifested may depend on the physical shape and size, of the chamber, such as by providing different diffusive effects that affect the distribution of ions in the chamber.

There is accordingly a general need in the art for improved systems for generating plasma that improve deposition thickness uniformity across the surface of substrates or layers previously formed thereover in HDP and ICP processes.

### SUMMARY

According to the present invention, methods and apparatus related to the field of semiconductor processing equipment are provided. More particularly, the present invention relates to methods and apparatus for depositing thin films, for example with gas distributors. Merely by way of example, the methods and apparatus of the present invention are used in HDP/CVD processes. The methods and apparatus can be applied to other processes for semiconductor substrates, for example those used in the formation of integrated circuits.

In one embodiment, a baffle for providing process gas into a processing volume of a vacuum process chamber is provided, the baffle comprising a body having a first end connectable to a gas source and a second end distal to the first end, the second end including at least a first frustoconical surface and a second frustoconical surface extending around the first frustoconical surface, and, an outer surface extending from the proximal end in the direction of the distal end, a first gas feed passage extending inwardly of the body from the proximal end thereof, the first gas feed passage terminating at a first passage distal end disposed inwardly of the body, at least one first discharge passage extending from the distal end of the first gas feed passage and opening through the first frustoconical surface, at least one second gas feed passage extending inwardly of the body from the proximal end thereof, the second gas passage terminating at a second gas passage distal end disposed inwardly of the body and fluidly isolated from the first gas feed passage, a second gas discharge passage extending from the second gas passage distal end and opening through the second frustoconical surface; and a third gas discharge passage extending from the second gas discharge passage and opening through the outer surface of the body at a location between the proximal end and the distal end of the body.

In another embodiment, a gas delivery system for a vacuum processing chamber is provided, the system comprising a baffle for providing process gas into a processing volume of a vacuum process chamber and a manifold connected to the baffle, the baffle comprising: a body having a first end connectable to a gas source and a second end distal to the first end, the second end including at least a first frustoconical surface and a second frustoconical surface extending around the first frustoconical surface, and, an outer surface extending from the proximal end in the direction of the distal end; a first gas feed passage extending inwardly of the body from the proximal end thereof, the first gas feed passage terminating at a first passage distal end disposed inwardly of the body; at least one first discharge passage extending from the distal end of the first gas feed passage and opening through the first frustoconical surface; at least one second gas feed passage extending inwardly of the body from the proximal end thereof, the second gas passage terminating at a second gas passage distal end disposed inwardly of the body and fluidly isolated from the first gas feed passage; a second gas discharge passage extending from the second gas passage distal end and opening through the second frustoconical surface; and a third gas discharge passage extending from the second gas discharge passage and opening through the outer surface of the body at a location between the proximal end and the distal end of the body, the manifold comprising: a first manifold gas feed passage fluidly connected to the first gas feed passage of the baffle; and a second manifold gas feed passage fluidly connected to the second gas feed passage of the baffle.

In another embodiment, a method of gas delivery is provided comprising; providing a baffle for providing process gas into a processing volume of a vacuum process chamber and a manifold connected to the baffle, the baffle comprising, providing a body having a first end connectable to a gas source and a second end distal to the first end, the second end including at least a first frustoconical surface and a second frustoconical surface extending around the first frustoconical surface, and, an outer surface extending from the proximal end in the direction of the distal end, extending a first gas feed passage inwardly of the body from the proximal end thereof, the first gas feed passage terminating at a first passage distal end disposed inwardly of the body, extending at least one first discharge passage from the distal end of the first gas feed passage and opening through the first frustoconical surface, extending at least one second gas feed passage inwardly of the body from the proximal end thereof, the second gas passage terminating at a second gas passage distal end disposed inwardly of the body and fluidly isolated from the first gas feed passage, extending a second gas discharge passage from the second gas passage distal end and opening through the second frustoconical surface, and extending a third gas discharge passage from the second gas discharge passage and opening through the outer surface of the body at a location between the proximal end and the distal end of the body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a cross-sectional view of a previously known gas distributor;

FIG. 2A is an isometric view of a multizone baffle

FIG. 2B is a top down view of the multizone baffle.

FIG. 2C is a bottom up view of the multizone baffle.

FIG. 3A is a cross sectional view of the multizone baffle of FIG. 2 in the distribution manifold.

FIG. 3B is a cross sectional view of the multizone baffle in the distribution manifold.

FIG. 4 is a cross sectional, top down view of the distribution manifold.

FIG. 5 is a cross sectional view of one aspect of the multizone baffle.

FIG. 6 is a cross sectional view of one aspect of the multizone baffle.

To facilitate understanding, identical reference numerals have been used, where possible, to designate identical elements that are common to the figures. It is contemplated that elements and features of one embodiment may be beneficially incorporated in other embodiments without further recitation.

According to the present invention, methods and apparatus related to the field of semiconductor processing equipment are provided. More particularly, the present invention relates to methods and apparatus for depositing thin films, for example with improved gas distributors, used in the formation of integrated circuits. Merely by way of example, the method and apparatus of the present invention are useful in HDP/CVD processes. The method and apparatus can be applied to other processes for semiconductor substrates, for example those used in the formation of integrated circuits.

Embodiments of the invention are useful in ULTIMA™ system manufactured by APPLIED MATERIALS, INC., of Santa Clara, Calif., a general description of which is provided in commonly assigned U.S. Pat. Nos. 5,994,662; 6,170,428; and 6,450,117; and U.S. patent application Ser. Nos. 10/963,030 and 11/075,527; the entire disclosures of these patents and applications are incorporated herein by reference.

### DETAILED DESCRIPTION

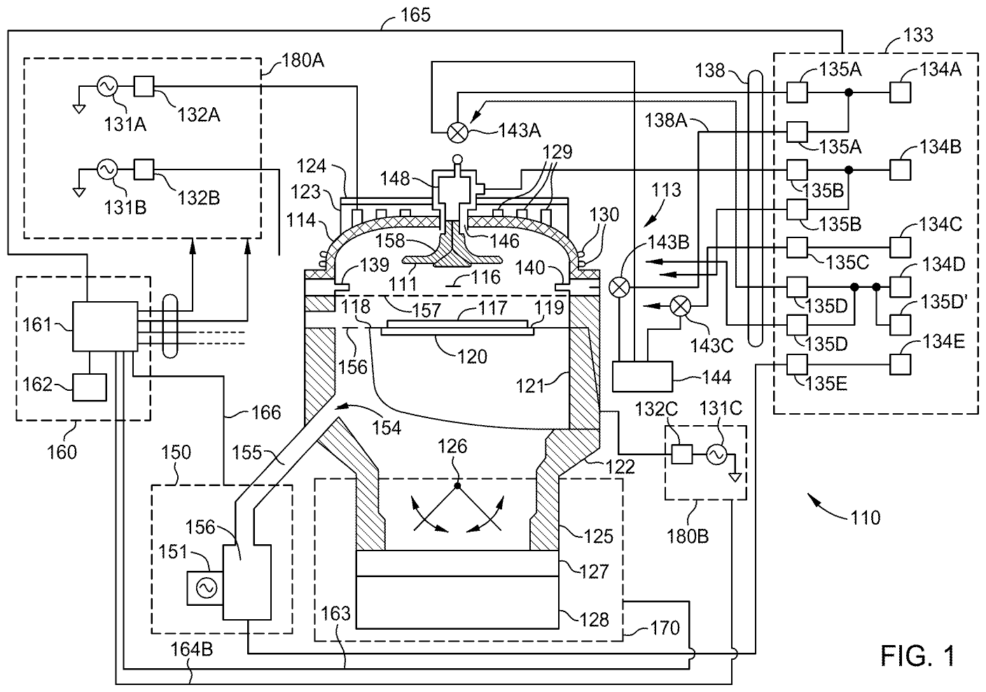

An overview of an ICP deposition system 110 is provided in connection with FIG. 1, which schematically illustrates the structure of an exemplary HDP-CVD system 110 in one embodiment. The system 110 includes a chamber 113, a vacuum system 170, a source plasma system 180A, a bias plasma generator system 180B, a gas delivery system 133, and a remote plasma cleaning system 150. Here, the chamber 113 is configured to include an inner process volume, here denoted a plasma processing volume 116, evacuated to a sub-atmospheric pressure using the vacuum system 170, and gases introduced into the plasma processing region can react to form a film layer on a substrate 117 receivable therein.

The upper portion of chamber 113 includes a dome 114, the inner surface of which defines one boundary of the of the plasma processing volume 117, which dome 114 is made of a ceramic dielectric material, such as aluminum oxide or aluminum nitride, sapphire, SiC or quartz through which an alternating frequency signal, such as RF, can penetrate. A heater plate 123 and a cold plate 124 surmount, and are thermally coupled to, the other side of the dome 114. Heater plate 123 and cold plate 124 together allow control of the dome 114 temperature to within about +10° C. over a range of about 100° C. to 200° C. Plasma processing region 116 is also bounded, inwardly of the dome 114, by the upper surface of a substrate 117 and a substrate support member 118.

The lower portion of chamber 113 includes a body member 122, which joins the chamber to the vacuum system. A base portion 121 of substrate support member 118 is mounted on, and forms a continuous inner surface with, body member 122 and surrounds the process volume of the chamber 113. Substrates are transferred into and out of chamber 113 by a robot blade (not shown) through an insertion/removal opening 152 in the side of chamber 113. Lift pins (not shown) are raised and then lowered under the control of a motor (also not shown) to move the substrate from the robot blade at an upper processing position 157 to a lower loading position 156 in which the substrate is placed on a substrate receiving portion 119 of substrate support member 118. Substrate receiving portion 119 may be configured to include an electrostatic chuck 120 that secures the substrate to substrate support member 118 during substrate processing. In a preferred embodiment, substrate support member 118 is configured to electrostatically chuck or secure a substrate 117 thereto, and is made from an aluminum oxide or aluminum based ceramic material.

Vacuum system 170 includes throttle body 125, which houses a twin-blade throttle valve 126 and is attached to gate valve 127 and turbo-molecular pump 128. It should be noted that throttle body 125 when open offers minimum obstruction to gas flow, and allows symmetric pumping. A gate valve 127 can be closed to isolate pump 128 from throttle body 125, and can also control chamber pressure by being partially closed restricting the exhaust flow capacity when throttle valve 126 is fully open. The arrangement of the throttle valve 126, gate valve 127, and turbo-molecular pump 128 allow for accurate and stable control of chamber pressures in the process volume from between about 1 millitorr to about 2 torr.

The source plasma system 180A includes a top coil 129 and side coil 130, mounted on dome 114 both on the outer surface of the dome and configured to inductively couple electrical energy into the plasma processing volume 116 of the chamber 117. A symmetrical ground shield (not shown) reduces electrical coupling between the top coil 129 and side coil 130. Top coil 129 is powered by top source (SRF) generator 131A, whereas side coil 130 is powered by side SRF generator 131B, allowing independent power levels and frequencies of operation for each coil. Each of the top SRF and side SRF provide an alternating current power to the coiled, for example and rf current, which inductively couples through the dome 114 into gases present in the plasma processing 116 to form and maintain a plasma thereof. This dual coil system allows control of the radial ion density in the plasma processing volume 116 of the chamber 113, thereby improving plasma uniformity. In a specific embodiment, the top source generator 131A provides up to 2,500 watts of alternating current power at nominally 2 MHz and the side source generator 131B provides up to 5,000 watts of alternating current power at nominally 2 MHz. The operating frequencies of the top and side generators 131A, B may be offset from the nominal 2 MHz operating frequency (e.g. to 1.7 1.9 MHz and 1.9 2.1 MHz, respectively) to improve plasma-generation efficiency.

A bias plasma system 180B includes a bias (“BRF”) generator 131 C and a bias matching network 132C. The bias plasma system 180B is configured to enhance the transport of plasma species (e.g., ions) created by the source plasma system 180A to the surface of the substrate or materials previously formed thereover for sputtering thereof. In a specific embodiment, bias generator 131C provides up to 5,000 watts of RF power at 13.56 MHz.

Top source generator and side source generators 131A and 131B include digitally controlled synthesizers and operate over a frequency range between about 1.8 to about 2.1 MHz. Each generator includes a control circuit (not shown) that measures reflected power from the chamber and coil back to the generator and adjusts the frequency of operation to obtain the lowest reflected power, as understood by a person of ordinary skill in the art. Such generators are typically designed to operate into a load with a characteristic impedance of 50 ohms. The alternating current power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the respective one of the generators to the plasma and protects the generator. Another way to reduce reflected power and improve efficiency is with a matching network.

Matching networks 132A and 132B match the output impedance of generators 131A and 131B with top coil 129 and side coil 130 and their loads, respectively. The control circuit may tune both matching networks by changing the value of capacitors within the matching networks to match the generator to the load as the load changes. The control circuit may tune a matching network when the power reflected from the load back to the generator exceeds a certain limit. One way to provide a constant match, and effectively disable the control circuit from tuning the matching network, is to set the reflected power limit above any expected value of reflected power. This may help stabilize a plasma under some conditions by holding the matching network constant at its most recent condition.

Other measures may also help stabilize a plasma. For example, the control circuit can be used to determine the power delivered to the load (plasma) and may increase or decrease the generator output power to keep the delivered power substantially constant during deposition of a layer.

A gas delivery system 133 provides gases from several sources, 134A-134E chamber for processing the substrate via gas delivery lines 138 (only some of which are shown). As would be understood by a person of skill in the art, the actual sources used for sources 134A-134E and the actual connection of delivery lines 138 to chamber 113 varies depending on the deposition and cleaning processes executed within chamber 113. Gases are introduced into chamber 113 through an outer gas ring 137 that surrounds the process volume and is located between the location of the substrate therein and the dome 114 and/or a gas distributor 111 centrally located and suspended from a gas manifold sealingly connected through an opening provided therefor in the center of the dome 114. In some embodiments, gas distributor 111 comprises a first passages adapted to inject a source gas, such as SiH₄ into the plasma processing volume 116, and second passages adapted to inject an oxidizer gas, such as O₂ into the plasma processing volume 116, which undergoes a chemical reaction with the source gas to form SiO₂ on the substrate 117 in the process volume or on the substrate 117.

In one embodiment, first and second gas sources, 134A and 134B, and first and second gas flow controllers, 135A′ and 135B′, provide gas to ring plenum in gas ring 137 via gas delivery lines 138 (only some of which are shown). Gas ring 137 has a plurality of source gas nozzles 139 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 137 has 12 source gas nozzles made from an aluminum oxide ceramic. In many embodiments, source gas nozzles 139 inject a source gas comprising SiH₄ into the chamber, which can be oxidized by an oxidizer gas, such as O₂, injected from oxidizer nozzles to form the dielectric layer.

Gas ring 137 also has a plurality of oxidizer gas nozzles 140 coupled to a second plenum separate from the silicon source gas supply (only one of which is shown), which in a preferred embodiment are co-planar with and shorter than source gas nozzles 139, and in one embodiment receive gas from body plenum. In some embodiments, it is desirable not to mix source gases and oxidizer gases before injecting the gases into chamber 113. In other embodiments, oxidizer gas and source gas may be mixed prior to injecting the gases into chamber 113 by providing apertures (not shown) between body plenum and gas ring plenum. In one embodiment, third, fourth, and fifth gas sources, 134C, 134D, and 134D′, and third and fourth gas flow controllers, 135C and 135D′, provide gas to body plenum via gas delivery lines 138. Additional valves, such as 143B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a 3-way valve, such as valve 143B, to isolate chamber 113 from delivery line 138A and to vent delivery line 138A to vacuum foreline 144, for example. As shown in FIG. 1B, other similar valves, such as 143A and 143C, may be incorporated on other gas delivery lines.

Chamber 113 also here includes a gas distributor 111 (or top nozzle or top baffle) and top inlet 146. Gas distributor 111 and top inlet 146 allow independent control of top and side flows of the gases, which improves film uniformity and allows fine adjustment of the film's deposition and doping parameters. Top inlet 146 is an annular opening around gas distributor 111. Gas distributor 111 includes a plurality of apertures in a step according to an embodiment of the present invention for improved gas distribution. In one embodiment, first gas source 134A supplies source gas nozzles 139 and gas distributor 111. Source nozzle multifunction controller (MFC) 135A′ controls the amount of gas delivered to source gas nozzles 139 and top nozzle MFC 135A controls the amount of gas delivered to gas distributor 111. Similarly, two MFCs 135B and 135B′ may be used to control the flow of oxygen to both top vent 146 and oxidizer gas nozzles 140 from a single source of oxygen, such as source 134B. The gases supplied to gas distributor 111 and top vent 146 may be kept separate prior to flowing the gases into chamber 113, or the gases may be mixed in top plenum 148 before they flow into chamber 113. Separate sources of the same gas may be used to supply various portions of the chamber. Plenum 148 may form a cavity of a remote plasma generator, configured to energize one or more gas species passing therethrough into radicals that are then injected into the plasma processing volume 116.

A remote microwave-generated plasma cleaning system 150 is provided to provide an activated cleaning gas to periodically clean deposition residues from the interior chamber components. The cleaning system includes a remote microwave generator 151 that creates a plasma from a cleaning gas source 134E (e.g., molecular fluorine, nitrogen trifluoride, other fluorocarbons or equivalents) in reactor cavity 153. The reactive species resulting from this plasma are conveyed to chamber 113 through cleaning gas feed port 154 via applicator tube 155. The materials used to contain the cleaning plasma (e.g., cavity 153 and applicator tube 155) must be resistant to attack by the plasma. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 120, do not need to be covered with a dummy wafer or otherwise protected, as may be required with an in situ plasma cleaning process.

System controller 160 controls the operation of system 110. In a preferred embodiment, controller 160 includes a memory 162, which comprises a tangible medium such as a hard disk drive, a floppy disk drive (not shown), and a card rack (not shown) coupled to a processor 161. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16-bit data bus and 24-bit address bus. System controller 160 operates under the control of a computer program stored on the tangible medium for example the hard disk drive, or through other computer programs, such as programs stored on a removable disk. The computer program dictates, for example, the timing, mixture of gases, alternating current (AC or RF) power levels and other parameters of a particular process. The interface between a user and the system controller is via a monitor, such as a cathode ray tube (“CRT”), and a light pen.

System controller 160 controls the season time of the chamber and gases used to season the chamber, the clean time and gases used to clean the chamber, and the application of plasma with the HDP CVD process. To achieve this control, the system controller 160 is coupled to many of the components of system 110. For example, system controller 160 is coupled to vacuum system 170, source plasma system 180A, bias plasma system 180B, gas delivery system 133, and remote plasma cleaning system 150. System controller 160 is coupled to vacuum system 170 with a line 163. System controller 160 is coupled to source plasma system 180 with a line 164A and to bias plasma system 1808 with a line 164B. System controller 160 is coupled to gas delivery system 133 with a line 165. System controller 160 is coupled to remote plasma cleaning system 150 with line 166. Lines 163, 164A, 164B. 165 and 166 transmit control signals from system controller 160 to vacuum system 170, source plasma system 180A, bias plasma system 1808, gas delivery system 133, and remote plasma cleaning system 150, respectively. For example, system controller 160 separately controls each of flow controllers 135A to 135E and 135A′ to 135D′ with line 165. Line 165 can comprise several separate control lines connected to each flow controller. It will be understood that system controller 160 can include several distributed processors to control the components of system 110.

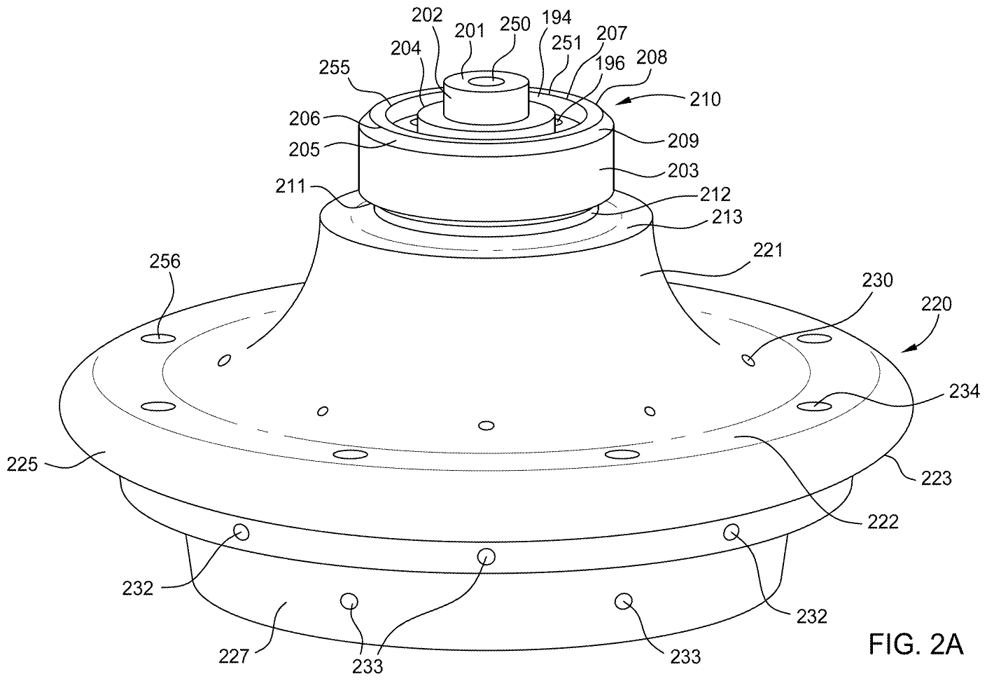

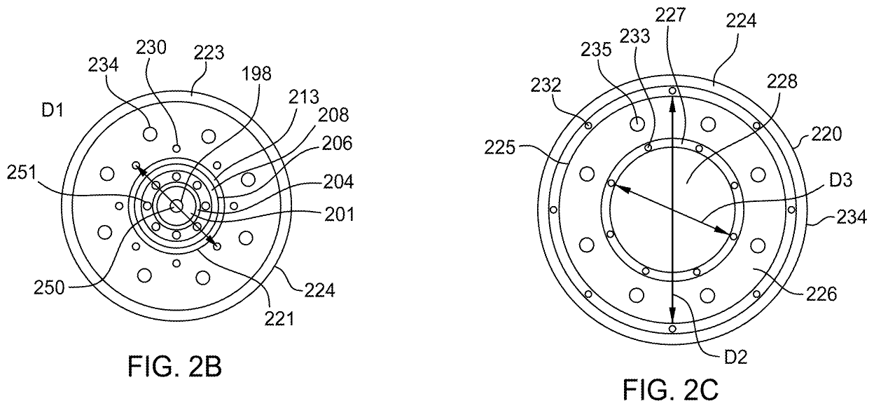

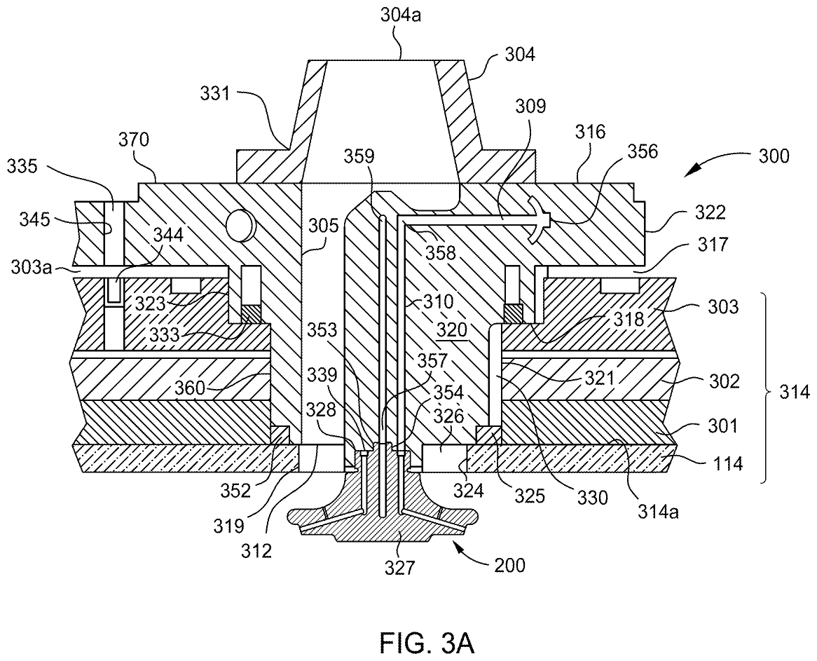

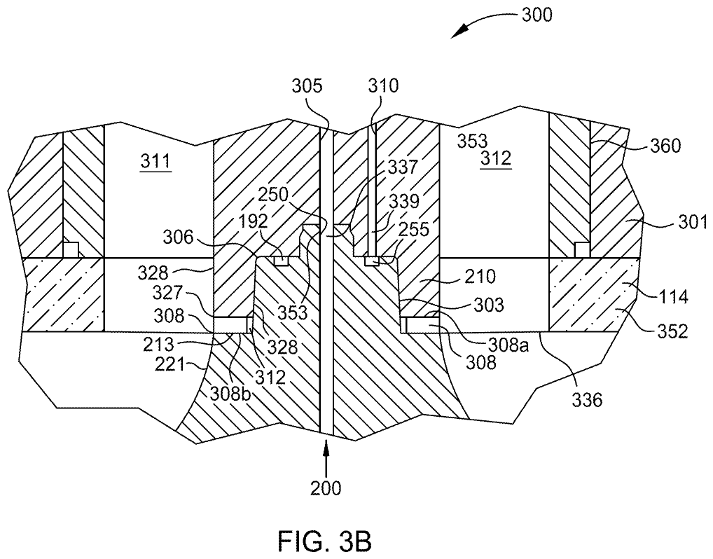

FIG. 2 shows an isometric view of a multizone baffle 200 comprising a proximal end 210 and a distal end 220, and FIG. 2B shows a top or plan view of the multizone baffle 200. The multizone baffle is here configured to direct process gasses directed to two different regions of a substrate through two different sets of gas passages therethrough, to direct process gases to the inner surface of the dome 114 generally adjacent to the center thereof, and to allow gasses passing through the annular top inlet 146 to pass through dedicated openings therethrough. Here, the top plenum 148 of FIG. 1 is replaced with a gas manifold, and the multizone baffle 200 is connected, at its proximal end, to the gas manifold 300 which is supported over the dome 114 by connection thereof to the temperature control plates 301, 302 and 303 as shown in FIG. 3A. Here, the multizone baffle 200 is rotationally symmetric about its longitudinal centerline 198 (FIG. 5), and is configured of quartz or a metal resistant to corrosion when exposed to the gasses used on the process volume.

The proximal end 210 of the multizone baffle 200 is configured to mate with corresponding features of the manifold 300, and includes a nipple 194 configured of a generally right cylindrical first neck surface 202 with a first annular manifold facing surface 201 extending orthogonal to and radially inwardly of the first neck surface 202, an annular second manifold facing surface 204 orthogonal to and extending radially outwardly of the first neck surface 202, the first manifold facing surface 201 disposed at the opposite end of the first neck surface 202 from the second manifold facing surface 204. The first manifold facing surface 201 contains an opening 250 generally centered about the baffle centerline 198 (FIG. 5), the opening 250 having a first opening circumference and opening into a first flow bore 250a (FIG. 5). An annular trough or recess 196, bounded inwardly of the body of the multizone baffle 200 from, and annularly bifurcating, the second manifold facing surface 204 by an annular third manifold facing surface 206, extends about and is generally centered about the baffle centerline 198. The inner and outer sidewalls 205, 207 of the recess 196 extend inwardly of the body of the multizone baffle 200 from the annular second manifold facing surface 204 and circumferentially about the baffle centerline 198, to reach the third manifold facing surface 206 which forms the base surface of a source gas plenum 192 (FIG. 3C) to be formed between the baffle 200 and the manifold 300, The third manifold facing surface 206 contains a plurality of openings 251 opening therethrough and evenly arcuately spaced from one another about the third manifold facing surface 206, for example 8 openings, each opening having a second opening circumference. Each of the second openings 251 forms the proximal end of a second flow passage 251a, and each of the second flow passages 251a extend inwardly of the body of the multizone baffle 200 from the third manifold facing surface 206, and these second flow passages 251a are evenly arcuately spaced from one another about the baffle centerline 198 of the multizone baffle 200.

A circumferential chamfered surface 209 extends at an angle from the outer circumference of the second manifold facing surface 204 and in the direction away from the first manifold facing surface 201. The chamfered surface 209 extends from the second manifold facing surface 204 to a threaded third neck surface 203. A first opposing surface 211 facing away from the manifold extends orthogonally from and inwardly of the third neck surface 203. A relief surface 212 extends orthogonally from and circumferentially from the first opposing surface 211. A third manifold facing surface 213 extends orthogonally from and outwardly of the relief neck surface 212. The first opposing surface 211, relief surface 212 and third manifold facing surface 213 together bound three sides of a thread relief groove, and the third manifold facing surface 213 extends radially outwardly of the outer perimeter of the first opposing surface to form a support ledge for a spacer or seal to be supported thereby against a surface of the manifold 300.

Referring to FIGS. 2A, 2B, 2C and 5, the distal end 220 of the multizone baffle 200 includes a curved flow directing surface 221 extending radially outwardly and away from the outer perimeter of the third manifold facing surface 213, which terminates at an annular fourth manifold facing surface 222. The curved flow directing surface 221 is a concave surface from the perspective of the dome 114, and it provides a curving flow or flow directing surface to direct gases impinging thereon from the direction of the dome 114 radially outwardly, as will be discussed herein. Additionally, the flow directing surface 221 includes a plurality of third openings 230 opening therethrough from within the body of the baffle 200, and a third opening flow passage 230a extends inwardly of the body from each of the third openings 230, For example eight third openings 230 are provided, each having a third opening circumference, and they are equally circumferentially spaced about the centerline 198 of the baffle 200 along a circular path centered about the centerline and intersecting the eight third opening flow passages 230a. The centers of the third openings are nominally located along an imaginary first circle centered at the centerline 198 of the baffle 200 having a first diameter D1 (FIG. 2B). The curved flow directing surface 221 terminates distal to the third manifold facing surface 213 at the annular fourth manifold facing surface 222 extending generally in parallel with the third manifold facing surface 213 and outwardly from the perimeter of the end of the curved flow directing surface 221. The fourth manifold facing surface 222 includes a plurality of fourth openings 234 extending therethrough and into the body of the baffle, for example 8 openings, equally circumferentially spaced about the centerline of the baffle. The plurality of fourth openings 234 on the fourth manifold facing surface 222 are arcuately spaced from the alignment of the location of the plurality of third openings 230 on the curved frustoconical surface 221. The fourth openings 234 are located along a circular path centered about the centerline 198 of the baffle 200, and located further from the centerline 198 of the baffle 200 as are the third openings 230. For example, where eight fourth openings 234 are present, they are equally spaced from one another, about the centerline of the baffle, by 45 degree along an imaginary fourth circle of diameter D4. Likewise, where eight third openings 230 are present, they are also spaced from one another about the centerline of the baffle by 45 degrees. The arcuate spacing between adjacent ones of these eight third openings 230 and the eight fourth openings 234 is here 22.5 degrees. The fourth manifold facing surface 222 terminates radially outwardly at, and blends into, a bullnosed edge surface 223 curving outwardly from the fourth manifold facing surface 222. The bullnose edge surface 223 rounds back toward the baffle centerline 198 to terminate at a first frustoconical surface 225 extending at an angle to, and at the radially inwardly circumferential end surface of, the portion of the bullnosed edge surface 223 facing away from the proximal end of the baffle 200. The first frustoconical surface 225 contains a plurality of fifth openings 232, for example eight such openings, opening thereat and connected to a fifth gas flow passage 232a extending inwardly of the body of the multizone baffle 200 (FIG. 5) and from which gas injected or flowed into second openings 251 of the baffle exits the baffle 200. The plurality of fifth openings 232 on the first frustoconical surface 225 are angularly (rotationally around the centerline) aligned with the locations of the plurality of third openings 230 angularly (rotationally around the centerline) on the curved surface 221. Likewise, the first frustoconical surface 225 generally extends at a first diameter from the baffle centerline 198, so that the centers of the fifth openings are nominally located on a third imaginary circle of a third diameter D2 from the centerline of the baffle 200. A second annular surface 226 extends inwardly of the first frustoconical surface 225 from the circumferential edge thereof distal to the proximal end of the baffle 200, and parallel to and facing away from the fourth manifold facing surface 222. The second annular surface 226 contains a plurality of sixth openings 235, for example, eight such openings equally spaced about the fourth imaginary circle D4, which form one end of a plurality of sixth flow passages 235a extending into the body of the baffle 200. The opposed ends of the sixth flow passages 235 open at one each of the plurality of fourth openings 234 on the fourth manifold facing surface 222. A second frustoconical surface 227 extends from and radially inwardly from the second annular surface 226 at a smaller diameter centered on the baffle centerline 200 than is the first frustoconical surface 225. The second frustoconical surface 227 contains a plurality of seventh openings 233, for example eight openings such formed at the ends of a corresponding eight second gas flow passages 233a (FIG. 5). The nominal centers of the seventh openings are located on an imaginary third circle of a diameter D3 centered on the baffle centerline 198

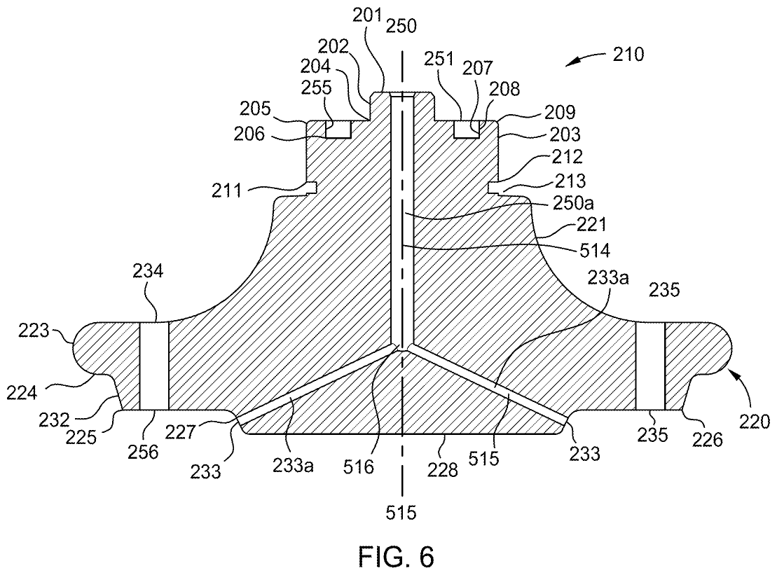

The multizone baffle 200 is configured to create four different flow paradigms or flow paths therethrough. This includes three active gas paths, and one passive gas path. As shown in FIG. 6, the plurality of second gas flow passages 233a extend inwardly of the baffle 200 from their openings (seventh opening 233) to connect to a first feed bore 250a extending inwardly of the baffle 200 and centered on the centerline to a distribution location 250b at the inward terminus of the first feed bore 250a inwardly of the baffle 200 to form a first active gas path. The first active gas path allows gas introduced into the first opening 250 to exit each of the eight different seventh openings 233. As shown in FIG. 5, the fifth gas flow passages 232a are connected, within the body of the multizone baffle 200, to the second flow passages 251a extending from the plenum in the second manifold facing surface 204 to form eight active second gas flow paths (two shown in FIG. 5) between openings 251 and openings 232. Each of the third flow passages 230a extending inwardly of the body of the multizone baffle also intersect the fifth gas flow passages 232a within the body of the baffle 200, between the connection thereof to one of the second flow passages 251a and to the openings 232. This forms a third active gas flow path, from the second openings 251 to the third gas openings 230.

As shown in FIG. 6, the passive gas path is provided between the curved surface 221 and the second annular surface 226 through the sixth flow passages 235a extending between one each of the fourth openings 234 and one each of the sixth flow openings 235. This allows gas on the curved surface side of the baffle to travel therethrough to the substrate facing side of the baffle 200.

Here, each of the third, fifth and second gas flow passages 230a, 232a and 233a are configured to extend perpendicular to their opening surface at the location of their respective openings 230, 232 and 233. As a result, the perimeter of each of the openings is, from a perspective looking down a centerline of the respective passage, a circle or nearly a circle, as opposed to elliptical or non-circular ovoid shaped. This results in predictable flow parameters of the gas passing out of the third, fifth and seventh openings 230, 232 and 233 by having minimal overhang of a portion of the sidewall of the third, fifth and seventh openings 230, 232 and 233 extending radially outwardly of other portions of the sidewall of the same opening. For example, the angle between the longitudinal axis of each of the third, fifth and second gas flow passages 230a, 232a and 233a, at the immediate outer surface of the baffle 200 where they open, is on the order of 90 degrees+/−0.5 degrees, or more preferably, 90 degrees+/−0.1 degree, or more preferably, 90 degrees+/−0.05 degrees. The third openings 230 and the connected flow passages 230a have a smaller circumference (diameter) than the fifth or the seventh openings 232, 233, and their respective connected fifth and second gas flow passages 232a, 233a. For example, the diameter and circumference of the third openings 230 is on the order of 30 to 70 percent of that of the openings 232, 233, more preferably 40 to 70 percent of that of the openings 232, 233, more preferably, for example, 50 percent of that of the openings 232, 233. As the proximal end of the multizone baffle 200 is supported by a gas manifold 300 over the dome 114 of the chamber, the gas flowing outwardly of the third openings 230 is directed toward the inner surface of the dome 114 immediately surrounding the connection of the baffle 200 to the manifold 300.

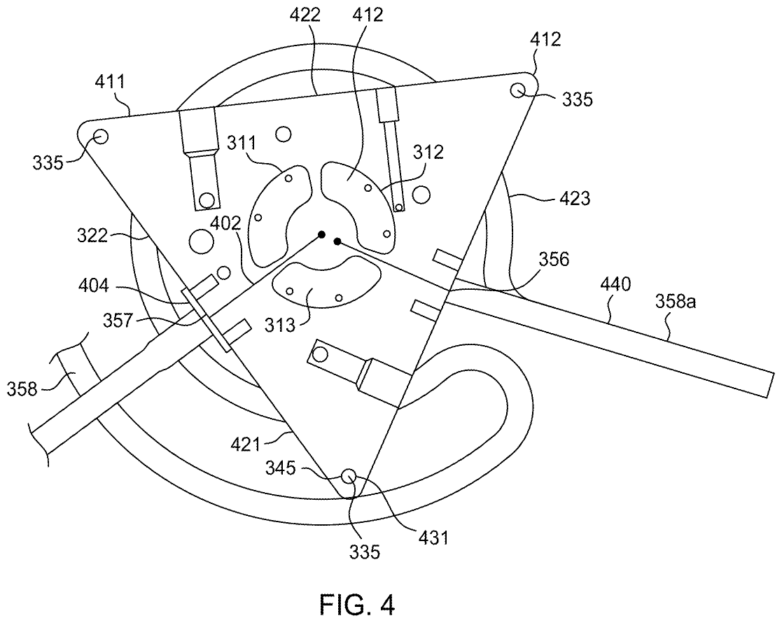

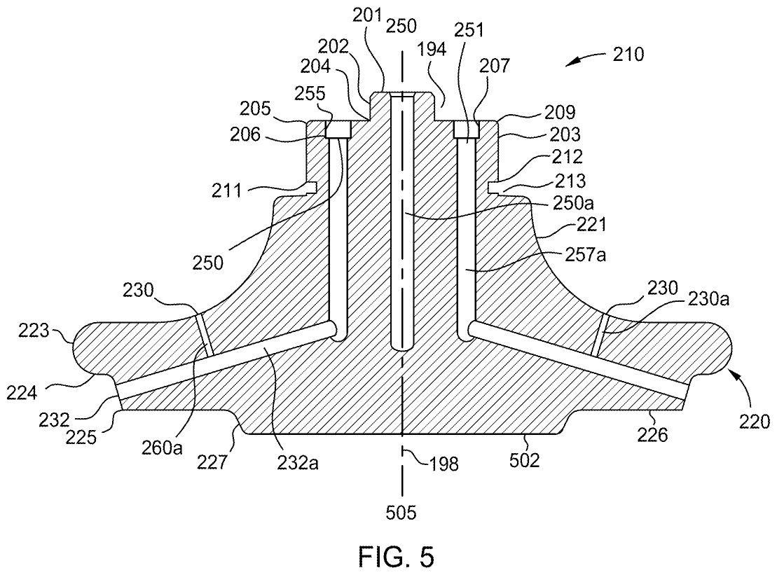

FIGS. 3A and 3B show the multizone baffle 200 of FIG. 2 disposed in the chamber (of FIG. 1) directly below the inner surface of the dome 114 of FIG. 1. The curved dome 114 forms a portion of a lid 314 assembly, which here includes a spacer plate 301, a first temperature control plate 302 and a second temperature control plate 303. The first temperature control plate 302 and the second temperature control plate 303 provide the functionality of the temperature control plates 123, 124 of FIG. 1, and the spacer plate 301 provides a gap between the top of the dome and the second temperature control plate 302 to protect the electrical coils 129 (FIG. 1) on the outer surface of the dome 114. The manifold 300 is connected to, and supports, the multizone baffle 200 that is suspended therefrom. The manifold 300 includes a manifold body 320 having a distal end 360 and a proximal end 370, and is partially disposed through a bore 330 in the lid assembly 314, such that the distal end thereof is positioned around, and partially inwardly of, a central opening 114a in the dome 114. The manifold body 320 is a material configured of, for example, stainless steel. The proximal end 370 of the manifold body 320 has a first planar surface 316 having a triangular perimeter (see FIG. 4) facing away and spaced from the lid assembly 314. The first planar surface 316 has a first surface flow opening 331 (FIG. 2A) having an opening circumference, and three first surface connection bore openings 335 extending through the proximal end 370 portion of the manifold body 320. Each of the three first surface connection bore openings 335 is disposed adjacent to one of the apices of the triangular perimeter of the triangularly shaped first planar surface 316. A first manifold perimeter wall surface 322 extends orthogonally from the first planar surface 316 and extends along and from the triangular perimeter of the first surface 316. The first manifold perimeter wall surface 322 contains a plurality of source gas flow openings, for example a first source gas flow opening 356 and a second source gas flow opening 357, opening into the surface thereof. A second planar surface 317 extends orthogonally from and inwardly of the first manifold perimeter surface 322 as an annular surface having a triangular perimeter wall distal to the first planar surface 316 and is generally parallel to first planar surface 316. The second planar surface 317 has a three second surface bore openings 338, each of the second surface bore openings 338 extending inwardly of the triangularly shaped second planar surface 317 and aligned with each of the three first surface bore openings 335 in the first planar surface 316. A second manifold perimeter surface 323 extends orthogonally from the second planar surface 317 and extends circumferentially and inwardly of the outer perimeter of the second planar surface 317. Here the second manifold perimeter surface 323 can be a generally right cylindrical surface having a circular cross section. A third planar surface 318 extends orthogonally from and inwardly of the second manifold perimeter surface 323 as an annular support surface distal to and generally parallel to the second planar surface 317. An annular bore 333 extends inwardly of the third planar surface 318 and can receive a seal therein. A third manifold perimeter surface 321 extends orthogonally from the inner perimeter of the third planar surface 318 in the direction away from the second planar surface 317. The third manifold perimeter surface 321 can be a generally right cylindrical surface having a circular cross section, which is smaller in diameter than the diameter of the second manifold perimeter surface 323. A fourth annular planar surface 319 extends orthogonally from and radially inwardly of the third manifold perimeter surface 321 to form a support ledge. A fourth manifold perimeter surface 325 extends orthogonally from the inner perimeter of the fourth planar surface 319 in the direction away from the second planar surface 317 and extends along the inner circumference of the fourth planar surface 319 as, for example, a right cylindrical surface that defines a circular perimeter. An annular fifth planar surface 324 extends orthogonally from and inwardly of the end of fourth manifold perimeter surface 325 distal to the annular fourth planar surface 324. The annular fifth planar surface 324 contains a plurality of arcuate, kidney shaped openings 336, for example, three kidney shaped openings 336 (see FIG. 4), opening thereat. A fifth manifold perimeter surface 326 extends orthogonally from the inner circumference of the annular fifth planar surface 324 and extends along the inner circumference of the annular fifth planar surface 324. An annular sixth planar surface 327 extends orthogonally from and inwardly of the perimeter of the annular fifth manifold perimeter surface 326. A baffle receiving bore, configured to receive the proximal end of the baffle 200 therein, is centered on and extends inwardly of the annular sixth planar surface 327, into which the second neck 203 of the baffle 200 is threaded to secure the baffle 200 to the manifold 300. The baffle receiving bore includes a threaded first baffle receiving bore surface 328 which extends orthogonally from and inwardly of the sixth planar surface 327, and is bounded inwardly of the annular sixth planar surface 327 at an annular seventh planar surface 329 extends radially inwardly of the threaded first baffle receiving bore surface 328. The annular seventh planar surface 329 contains a recessed opening 339. A second baffle receiving bore surface 354 extends orthogonally from and inwardly of the annular seventh planar surface 329. An annular eighth planar surface 353 extends orthogonally from and radially inwardly from the inner base of the second baffle receiving bore surface 354. The annular eighth planar surface 353 includes an opening 337 having a circumference generally centered thereon.

The manifold body 320 is partially disposed through the bore 330 in the lid assembly 314, including a continuous bore 340 through spacer layer 301 and the first temperature control layer 302, and a stepped bore 341 in the second temperature control layer 303. The second temperature control layer 303 also has first planar surface 303a having three third heater bore openings 344 extending thereinto, each bore opening 344 having a bore extending at least partially into the third heating layer 303. The third heater bore openings 344 may be directly threaded or include a threaded insert press fit or adhesively secured therein, and are located along the apices of a triangle corresponding the location of the first surface bore openings 335.

The three first manifold securement bores 345 each extend from one of the three first surface bore openings 335 to one of the three second surface bore openings 338 to allow a threaded fastener, to be extended therethrough. When the manifold body 320 is assembled into the lid 314 and into corresponding bores 340, 341 in the lid assembly 314, the three first manifold bores 345 are aligned with the three third temperature control layer heater bore openings 344. A fastener, such as a threaded bolt (not shown), is inserted through the first manifold bores 345 and threaded into the third heater bore openings 344 so that the third annular surface 318 of the manifold body 320 is in contact with an annular support ledge 318 in the first planar surface 303a of the annular recess in the third heating layer 303, thus securing the manifold body 320 into the lid assembly 314.

A seal for example, an annular sealing ring 352, is placed in a generally rectangular in section opening between the inner surface of the opening through the spacer layer 301, the fourth manifold perimeter surface 326, the annular fourth planar surface 319 of the manifold body 320, and the outer (upper) surface 314a of the dome 114. The sealing ring 352 may comprise an O-ring, a lip seal, a spring loaded lip seal, or other seal configurations.

Referring to FIGS. 3A and 4, a plurality of fourth manifold bores 311, 312, and 313 (FIG. 4), for example 3 manifold bores, extend from the three kidney shaped openings 336 on the fifth planar surface 324 of the manifold body 320, inwardly of the fifth planar surface 324, to the first surface flow opening 331 of the first planar surface 316. These manifold bores 311 to 313 are configured to allow a gas to pass therethrough and into the plasma processing volume of the chamber.

A fifth manifold bore 310 extends from the recessed opening 339 on the annular seventh planar surface 329 of the manifold body 320, inwardly of in the direction generally orthogonal to the seventh planar surface 329, terminating at a first flow junction 358 disposed inwardly of the manifold body 320 on a plane 1-1, which is the cur plane of the manifold body 320 for the view thereof in FIG. 4. The fifth manifold bore 310 extends generally parallel to the centerline of the manifold body 320, and is radially offset to the side thereof. A sixth manifold bore 309 extends within plane A-A from the first remote flow opening 356 to the first flow junction 358 at the terminal end of the fifth manifold bore 310 inwardly of the manifold body 320. Thus the fifth manifold bore 310 and the sixth manifold bore 309 meet at the terminus junction 358 at a 90 degree angle, the fifth manifold bore 310 in fluid communication with the sixth manifold bore 309. To supply a process gas to the manifold 300, and thus into the baffle 200, a first gas supply pipe 401, (see FIG. 4) is attached to the manifold perimeter surface 322 at the first remote flow opening 356, allowing gas or another fluid to be introduced from the first remote flow opening 356, through the manifold body 320, and thence to the recessed opening 339.

A seventh manifold bore 305 extends from the opening 337 on the eighth planar surface 353 of the manifold body 320, inwardly of the eighth planar surface 353, terminating at a second flow junction 359 inwardly of the manifold body 320 on a plane 1-1. Here, the seventh manifold bore 305 is centered on and extends along the centerline of the manifold body 320. An eighth manifold bore 402, (see FIG. 4) extends from the second remote flow opening 357 to the second flow junction 359 at the terminus of the seventh manifold bore 305 inwardly of the manifold body 320. Thus the seventh manifold bore 305 and the eighth manifold bore 402 meet and are in fluid communication at the terminus 359 at a 90 degree angle, the seventh manifold bore 305 in fluid communication with the eighth manifold bore 402. A second gas supply pipe 401a, (see FIG. 4) is attached to the manifold perimeter surface 322 at the second remote flow opening 356, allowing gas or another fluid to be introduced from the second remote flow opening 356 into the seventh manifold bore 305.

Each of the conduits 401, 401a is connected through its own valving and different mass flow controller and associated to control hardware to enable independent metered and controlled flow of a source gas to the first and second source gas openings 365, 357, and thence through and out of the plurality of fourth manifold bores 230, 232 and 233.

To supply gas into the arcuate openings 311, 312 and 333 extending through the manifold body 320, a gas source conduit 304 containing a flow bore 304a therein is sealingly connected to the first planar surface 316 of the manifold body 320 as shown in FIG. 3A. A flange on the gas source conduit surrounds the first surface flow opening 331 so that the flow bore 304a is in fluid communication with the first surface flow opening 331. The flow bore 304a may have the same circumference as the first surface flow opening 331. The gas source conduit 304 may be attached to a gas plenum or may form a part of, or be in fluid connected communication with, a remote plasma source, or other gas source. A gas flowing through the a flow bore 304a will enter the manifold body 320 at the first surface flow opening 331, flow through the plurality of fourth manifold bores 311,312, and 313 (see FIG. 4), and exit through the three kidney shaped openings 336 and thus into the plasma processing region of the process chamber in the region thereof between the curved surface 321 of the baffle 200 and the inner surface of the dome 114.

The proximal end 210 of the multizone baffle 200 is secured within the distal end 360 of the manifold body 320, such as by threading the third neck surface 203 of the baffle 200 into the first baffle receiving bore 328. The eighth planar surface 353 containing the opening 337 is in fluid communication with the first manifold facing surface 201 of the baffle 200 containing the opening 250 so that opening 337 is sealingly connected to opening 250. An O-ring, a gasket, or other sealing material may be employed surrounding the opening 337 to seal the interface between the eighth planar surface 353 and the first manifold facing surface 201 of the baffle 200. The circumference of the opening 337 in the manifold body may be of the same size as the circumference of the opening 250 in the baffle 200. The first neck surface 202 of the baffle 200 extends inwardly of the bore created by the seventh neck surface 354 of the manifold 300. The seventh planar surface 329 containing opening 339 of the manifold body 320 is sealingly connected to and in fluid communication with both the second manifold facing surface 204 and the fourth manifold facing surface 208 of the baffle 200. When the baffle 200 is sealingly secured to the manifold body 320, a sealed plenum 255 is formed extending inwardly of the second manifold facing surface 204 of the baffle 200 . . . . Thus gas flowed through the opening 339 of the manifold body 300 will flow into the openings 251 in the third manifold facing surface 206.

A seal ring such as an O-ring or other annular ring 308 having a first surface 308a and a second surface 308b comprising a material compatible with the fluids passing through the baffle 200 and the manifold 300 is located on the fifth manifold facing surface 213 of the baffle 200, whereby the second surface 308b is in contact with the fifth manifold facing surface 213 of the baffle 200 to seal off the interface therebetween. The inner circumference of the ring 308 is configured to surround the relief surface 212 and disposed under the first opposing surface 211, the first surface 308a in contact with the first opposing surface 211 of the baffle 200. The outer circumference of the ring 308 is, for example, the same outer circumference as that of the fifth manifold facing surface 213. The sixth planar surface 327 of the manifold 300 is in contact with the portion of the first surface 308a of the ring 308 that is not in contact with the first opposing surface 211.

When the multizone baffle 200 is secured in the manifold 300, the kidney shaped openings 336 are above the fourth manifold facing surface 222 and the curved surface 221, and thus in direct line of sight of the through fourth passages 324. Material flowed through the fourth manifold bores 311,312 and 313 will exit out of the kidney shaped openings 336 and flow over the fourth manifold facing surface 222, the curved surface 221, and over the sides of the bullnosed edge surface 223 of the baffle 200. Material flowed through the fourth manifold bores 311,312 and 313 will season the fourth manifold facing surface 222 and the curved surface 221 of the baffle 200. Material flowed through the fourth manifold bores 311,312, and 313 will also pass through the through bores 256 of the baffle 200, entering through the plurality of fourth openings 234 on the fourth manifold facing surface 222, flowing through the plurality of through bores 256 and exiting through the plurality of openings 233 on the second annular surface 226. Thus, gas flowed through the fourth manifold bores 311,312 and 313 will flow to an area surrounding the baffle 200 and an area under the baffle 200.

In use, the baffle 200 is configured to emit gas from the openings therein, and allow gas located between the baffle 200 and the inner wall of the dome 114 to flow through the passive openings extending therethrough. Additionally, the manifold 300 is configured to be connected to a remote plasma source, and the remote plasma source is fluidly connected to the fourth manifold bores 311, 312 and 313. The gas flowing though the remote plasma source may be energized into excited radicals by having passed through a plasma region in the remote plasma source. Alternatively, the remote plasma source can also be used as a gas supply without forming the plasma in the plasma region thereof, such that a gas in its non-energized (non-excited state can be passed therethrough and thus through the fourth conduits 311, 312 and 313.

Specifically, gas flowing into the manifold 300 through conduit 401 flows into the fifth manifold bore 310, which in turn flows into the plurality of second flow passages 251a, and thence outwardly of the third openings 230 and fifth openings 232. The flow rate of the gas flowing into the fifth manifold bore 310 is controlled by a first one of the flow controllers (MFC's) 135A. Gas flowing through a second, flow controllers (MFC's) 135A, different than the first one of the flow controllers (MFC's) 135A, is supplied through conduit 401A, into the seventh manifold bore 305, thence into the first flow bore 250A to flow outwardly of the seventh openings 233 of the baffle 200. By employing different MFC's 135A for the gas flowing outwardly of the fifth openings 232 and the seventh openings 233, the user of the system can vary the different flow settings of the gas to these openings to tune the resulting deposition (or etch) uniformity across the surface of the substrate.

Additionally, the angle of the gas stream emitted from the fifth openings 232 and the seventh openings 233 can be different. For example, the angle between the secterline 198 of the baffle and the first frustoconical surface 225, or first frustoconical angle 252 and the angle between second frustoconical surface 227 and the centerline 198 of the baffle, or second frustoconical angle 254, are different. For example, the first frustoconical angle 252 is greater than that of the second frustoconical angle 254. Likewise, the fifth gas flow passage 232a centerline 258 extends at a fifth flow passage angle 260, which is different than the second flow passage angle 264 between the second gas flow passage centerline 262 and the baffle centerline 198.

For example, to form a silicon oxide layer on a substrate in the plasma processing volume 116 of the chamber, a silicon source gas is flowed into the openings 356, 357 in the perimeter surface 322 of the manifold body 320, This silicon source gas flows through the bores or passages in the manifold body 320, into the flow passages in the baffle 200, and thence outwardly of third openings 230, fifth openings 322 and seventh openings 233 of the baffle 200 and thence into the process volume. An oxygen containing gas, for example O₂, O₃, H₂O or another oxygen source gas is flowed through the remote plasma source and thence through the fourth conduits 311, 312 and 313. This oxygen containing gas flows along the curved surface 221 of the baffle and out over the edge profile of the baffle 200 to reach the region circumferentially around the baffle 200. A portion of this oxygen gas flows though the pass through bores 256 in the baffle 200 into the portion of the plasma processing region 116 between the baffle 200 and the substrate 117 on the substrate support 120. The placement of the fifth openings 232 and seventh openings 233 to open on frustoconical surfaces allows the openings to be circular in section, rather than elliptical or other compound ovoid construct. The silicon source gas exiting the fifth openings 232 and seventh openings 233 reaches the center and intermediate annular portions of the facing surface of the substrate, to react with the oxygen gas to form a silicon oxide film. The silicon source gas from the source gas nozzles 139 and any oxygen gas from the oxidizer nozzles 140 injected into the process region form silicon oxide layer on the outer annular region of the substrate. However, gas injected from the source gas nozzle 139 and oxidizer nozzles 140 can reach the middle annular and central regions of the substrate. Likewise, gas injected from the fifth and seventh openings 232, 233 of the baffle 200 can reach the outer perimeter of the substrate.

Similarly, a silicon nitride layer can be formed on the substrate by substituting a nitrogen source gas for the oxygen source gas, and as N₂ or NH₃. An oxynitride film can be formed using a nitrogen and oxygen gas in place of only the oxygen source gas or only the nitrogen source gas. By varying the flow rates of the silicon source gas entering the first and second source gas flow openings 356, 357 thus exiting third openings 320, fifth openings 232 and seventh openings 233 in the baffle and that exiting the source gas nozzles 139 of the gas ring 137, one skilled in the art can determine appropriate flow rates to deposit a film layer on a substrate having a within substrate thickness variation of less than XX %. Likewise, varying the flow quantities of the reactant gas (O, N ON, etc.) compared to the silicon source gas supplied, one skilled in the art can deposited silicon with or silicon deficient layers.

The flow of the silicon source gas through the third opening 230 in the baffle also is useful to form a silicon or silicon based passivation or protective layer on the inner, process region facing, surface of the dome 114. For example, a silicon source gas can be directed through the baffle openings and that gas ejected from the third openings 230 contacts and forms a protective layer on the inner surface of the dome 114. This may include a silicon, silicon oxide, silicon nitride, silicon oxynitride, etc. based passivation layer. The non-silicon portion of the passivation layer is supplied through the remote plasma source, in an activated or non-activated state.

The remote plasma source is also useful to provide a cleaning gas such as a flouring based gas into the process volume of the chamber, to clean the surfaces of the baffle 200, the inner surface of the dome 114 and other inner surfaces of the chamber. This gas flows over the curved surface 221 of the baffle and can reach the inner surface of the dome 114 or of the passivation layer thereon to remove undesirable deposits therefrom. The activated gas will also pass through the pass-through openings in the baffle, to remove deposits (clean) from the walls thereof, and reach the substrate facing side of the baffle 200 to remove deposits (clean) those surface.

While the foregoing is directed to embodiments of the present disclosure, other and further embodiments of the disclosure may be devised without departing from the basic scope thereof, and the scope thereof is determined by the claims that follow.

What is claimed is:

1. A baffle for providing process gas into a processing volume of a vacuum process chamber, comprising:
a body having a first end connectable to a gas source and a second end distal to the first end, the second end including at least a first frustoconical surface and a second frustoconical surface extending around the first frustoconical surface, and, an outer surface extending from the proximal end in the direction of the distal end;
a first gas feed passage extending inwardly of the body from the proximal end thereof, the first gas feed passage terminating at a first passage distal end disposed inwardly of the body;
at least one first discharge passage extending from the distal end of the first gas feed passage and opening through the first frustoconical surface;
at least one second gas feed passage extending inwardly of the body from the proximal end thereof, the second gas passage terminating at a second gas passage distal end disposed inwardly of the body and fluidly isolated from the first gas feed passage;
a second gas discharge passage extending from the second gas passage distal end and opening through the second frustoconical surface; and
a third gas discharge passage extending from the second gas discharge passage and opening through the outer surface of the body at a location between the proximal end and the distal end of the body.

2. The baffle of claim 1, wherein the first gas discharge passage has a first inner diameter, the second gas discharge passage has a second inner diameter, and the third gas discharge has a third inner diameter, and the third inner diameter of the third gas discharge passage is less than the second inner diameter of the second gas discharge passage.

3. The baffle of claim 1, wherein the body includes a centerline, and the outer surface of the body is circumferentially symmetric about the centerline and the first and the second frustoconical surfaces are circumferentially symmetric about the centerline.

4. The baffle of claim 3, wherein the at least one first discharge passage includes a plurality of first discharge passages opening through the first frustoconical surface and equally spaced from one another circumferentially.

5. The baffle of claim 3, further comprising a plurality of through passages extending through the body and opening through the outer surface of the body and through the second end of the body.

6. The baffle of claim 3, wherein the plurality of through passages open through the second end between the first frustoconical surface and the second frustoconical surface.

7. The baffle of claim 3, wherein the first gas discharge passage extends perpendicularly to the first frustoconical surface at the location where the first gas discharge passage opens through the first frustoconical surface and the second gas discharge passage extends perpendicularly to the second frustoconical surface at the location where the first gas discharge passage opens through the first frustoconical surface.

8. A gas delivery system for a vacuum processing chamber, comprising:
a baffle for providing process gas into a processing volume of a vacuum process chamber and a manifold connected to the baffle:
the baffle comprising:
a body having a first end connectable to a gas source and a second end distal to the first end, the second end including at least a first frustoconical surface and a second frustoconical surface extending around the first frustoconical surface, and, an outer surface extending from the proximal end in the direction of the distal end;
a first gas feed passage extending inwardly of the body from the proximal end thereof, the first gas feed passage terminating at a first passage distal end disposed inwardly of the body;
at least one first discharge passage extending from the distal end of the first gas feed passage and opening through the first frustoconical surface;
at least one second gas feed passage extending inwardly of the body from the proximal end thereof, the second gas passage terminating at a second gas passage distal end disposed inwardly of the body and fluidly isolated from the first gas feed passage;
a second gas discharge passage extending from the second gas passage distal end and opening through the second frustoconical surface; and
a third gas discharge passage extending from the second gas discharge passage and opening through the outer surface of the body at a location between the proximal end and the distal end of the body
the manifold comprising:
a first manifold gas feed passage fluidly connected to the first gas feed passage of the baffle; and
a second manifold gas feed passage fluidly connected to the second gas feed passage of the baffle.

9. The gas delivery system of claim 8, wherein the first gas discharge passage of the baffle has a first inner diameter, the second gas discharge passage of the baffle has a second inner diameter, and the third gas discharge passage of the baffle has a third inner diameter, and the third inner diameter of the third gas discharge passage is less than the second inner diameter of the second discharge passage.

10. The gas delivery system of claim 8, wherein the body of the baffle includes a centerline, and the outer surface of the body is circumferentially symmetric about the centerline and the first and the second frustoconical surfaces are circumferentially symmetric about the centerline.

11. The gas delivery system of claim 10, wherein the at least one first discharge passage of the baffle includes a plurality of first discharge passages opening through the first frustoconical surface and equally spaced from one another circumferentially.

12. The gas delivery system of claim 10, the baffle further comprising a plurality of through passages extending through the body and opening through the outer surface of the body and through the second end of the body; and
the manifold including a plurality of manifold through gas passages therethrough, an opening of manifold through gas passage overlying the outer surface of the baffle.

13. The gas delivery system of claim 10, wherein the plurality of through passages open through the second end between the first frustoconical surface and the second frustoconical surface.

14. The gas delivery system, wherein the first gas discharge passage extends perpendicularly to the first frustoconical surface at the location where the first gas discharge passage opens through the first frustoconical surface and the second gas discharge passage extends perpendicularly to the second frustoconical surface at the location where the first gas discharge passage opens through the first frustoconical surface.

15. A method of gas delivery comprising:
providing a baffle for providing process gas into a processing volume of a vacuum process chamber and a manifold connected to the baffle, the baffle comprising;
providing a body having a first end connectable to a gas source and a second end distal to the first end, the second end including at least a first frustoconical surface and a second frustoconical surface extending around the first frustoconical surface, and, an outer surface extending from the proximal end in the direction of the distal end;
extending a first gas feed passage inwardly of the body from the proximal end thereof, the first gas feed passage terminating at a first passage distal end disposed inwardly of the body;
extending at least one first discharge passage from the distal end of the first gas feed passage and opening through the first frustoconical surface;
extending at least one second gas feed passage inwardly of the body from the proximal end thereof, the second gas passage terminating at a second gas passage distal end disposed inwardly of the body and fluidly isolated from the first gas feed passage;
extending a second gas discharge passage from the second gas passage distal end and opening through the second frustoconical surface; and
extending a third gas discharge passage from the second gas discharge passage and opening through the outer surface of the body at a location between the proximal end and the distal end of the body.

16. The method of claim 15, wherein the first gas discharge passage of the baffle has a first inner diameter, the second gas discharge passage of the baffle has a second inner diameter, and the third gas discharge passage of the baffle has a third inner diameter, and the third inner diameter of the third gas discharge passage is less than the second inner diameter to the second discharge passage.

17. The method of claim 15, wherein the body of the baffle includes a centerline, and the outer surface of the body is circumferentially symmetric about the centerline and the first and the second frustoconical surfaces are circumferentially symmetric about the centerline.

18. The method of claim 17, wherein the at least one first discharge passage of the baffle includes a plurality of first discharge passages opening through the first frustoconical surface and equally spaced from one another circumferentially.

19. The method of claim 17, the baffle further comprising a plurality of through passages extending through the body and opening through the outer surface of the body and through the second end of the body; and
the manifold including a plurality of manifold through gas passages therethrough, an opening of manifold through gas passage overlying the outer surface of the baffle.

20. The method of claim 17, wherein the plurality of through passages open through the second end between the first frustoconical surface and the second frustoconical surface.
